(19) United States
(12) Patent Application Publication
(10) Pub. No.: US 2017/0106628 A1
(43) Pub. Date: Apr. 20, 2017

(54) METALLIC DECORATIVE PART FOR VEHICLE DISPLAY DEVICE, AND VEHICLE DISPLAY DEVICE

(71) Applicant: Yazaki Corporation, Tokyo (JP)

(72) Inventors: Tatsuya HATTORI, Shizuoka (JP); Sunao FUJITA, Shizuoka (JP)

(21) Appl. No.: 15/295,855

(22) Filed: Oct. 17, 2016

(30) Foreign Application Priority Data
Oct. 19, 2015 (JP) 2015-205790

(51) Int. Cl. B32B 15/08; B60K 35/00; B60R 13/02

(52) U.S. Cl. CPC B32B 15/08; B60R 13/02; B60K 35/00; B32B 2605/00; B60K 2350/40

(57) ABSTRACT

A metallic decorative part for a vehicle display device includes a substrate body molded with synthetic resin, a metal thin film formed of metal and deposited on a surface of the substrate body, and a ridge that is formed with different surfaces intersecting at a surface of the metal thin film in conformity with a shape of the surface of the substrate body. The ridge is formed such that a curvature radius of a corner that forms an apex of the ridge is greater than 0 and equal to or smaller than 28.0 μm.

### CROSS-REFERENCE TO RELATED APPLICATION(S)

The present application claims priority to and incorporates by reference the entire contents of Japanese Patent Application No. 2015-205790 filed in Japan on Oct. 19, 2015.

### BACKGROUND OF THE INVENTION

1. Field of the Invention

The present invention relates to a metallic decorative part for a vehicle display device, and to a vehicle display device.

2. Description of the Related Art

Japanese Patent Application Laid-open No. 2007-232403, for example, discloses a decorative member for a vehicle instrument as a known metallic decorative part for a vehicle display device to be applied to a vehicle display device. The decorative member includes a substrate, a primer layer, and a metal coating. The substrate is formed of a light-transmissive material and a display design is formed thereon. The primer layer and the metal coating are stacked in sequence on portions of the substrate excluding a front surface of the substrate and a front surface of the display design.

The decorative member disclosed in Japanese Patent Application Laid-open No. 2007-232403 needs further improvement to exhibit more appropriate metallic texture.

### SUMMARY OF THE INVENTION

The present invention has been made in view of the foregoing situation and it is an object of the present invention to provide a metallic decorative part for a vehicle display device, and a vehicle display device, that can achieve appropriate metallic texture to be given to a viewer in a configuration including a metal thin film on a surface of a substrate body formed of resin.

In order to achieve the above mentioned object, a metallic decorative part for a vehicle display device according to one aspect of the present invention includes a substrate body molded with synthetic resin; a metal thin film that is formed of metal and deposited on a surface of the substrate body; and a ridge that is formed with different surfaces intersecting at a surface of the metal thin film in conformity with a shape of the surface of the substrate body, wherein the ridge is formed such that a curvature radius of a corner that forms an apex of the ridge is greater than 0 and equal to or smaller than 28.0 μm.

According to another aspect of the present invention, in the metallic decorative part for a vehicle display device, the ridge may be formed such that the curvature radius of the corner that forms the apex of the ridge is greater than 0 and equal to or smaller than 10.0 μm.

According to still another aspect of the present invention, in the metallic decorative part for a vehicle display device, an angle formed by the different surfaces that form the ridge may be greater than 90°.

In order to achieve the above mentioned object, a vehicle display device according to still another aspect of the present invention includes a display unit that displays information relating to vehicle; and a metallic decorative part for a vehicle display device that includes a substrate body molded with synthetic resin, a metal thin film that is formed of metal and deposited on a surface of the substrate body, and a ridge that is formed with different surfaces intersecting at a surface of the metal thin film in conformity with a shape of the surface of the substrate body, wherein the ridge is formed such that a curvature radius of a corner that forms an apex of the ridge is greater than 0 and equal to or smaller than 28.0 μm.

The above and other objects, features, advantages and technical and industrial significance of this invention will be better understood by reading the following detailed description of presently preferred embodiments of the invention, when considered in connection with the accompanying drawings,

### BRIEF DESCRIPTION OF THE DRAWINGS

FIG. 1 is a front view illustrating an overall configuration of a vehicle display device according to an embodiment;

FIG. 2 is a partial sectional view along A-A in FIG. 1;

FIG. 3 is a front view illustrating an overall configuration of a dial plate applied to the vehicle display device according to the embodiment;

FIG. 4 is a schematic sectional view illustrating an overall configuration of the dial plate applied to the vehicle display device according to the embodiment;

FIG. 5 is a schematic diagram illustrating the curvature radius of the corner that forms the apex of a groove in the dial plate applied to the vehicle display device according to the embodiment;

FIG. 6 is a chart illustrating an example of measurement data for the dial plate applied to the vehicle display device according to the embodiment; and

FIG. 7 is a diagram illustrating the results of a sensory evaluation test for the dial plate according to examples.

### DETAILED DESCRIPTION OF THE PREFERRED EMBODIMENTS

The following describes in detail a preferred embodiment according to the present invention. The embodiment is, however, presented by way of example only and is not intended to limit the scope of the invention. Additionally, components of the embodiment include those that can be replaced by those skilled in the art and simple or substantially identical ones.

### Embodiment

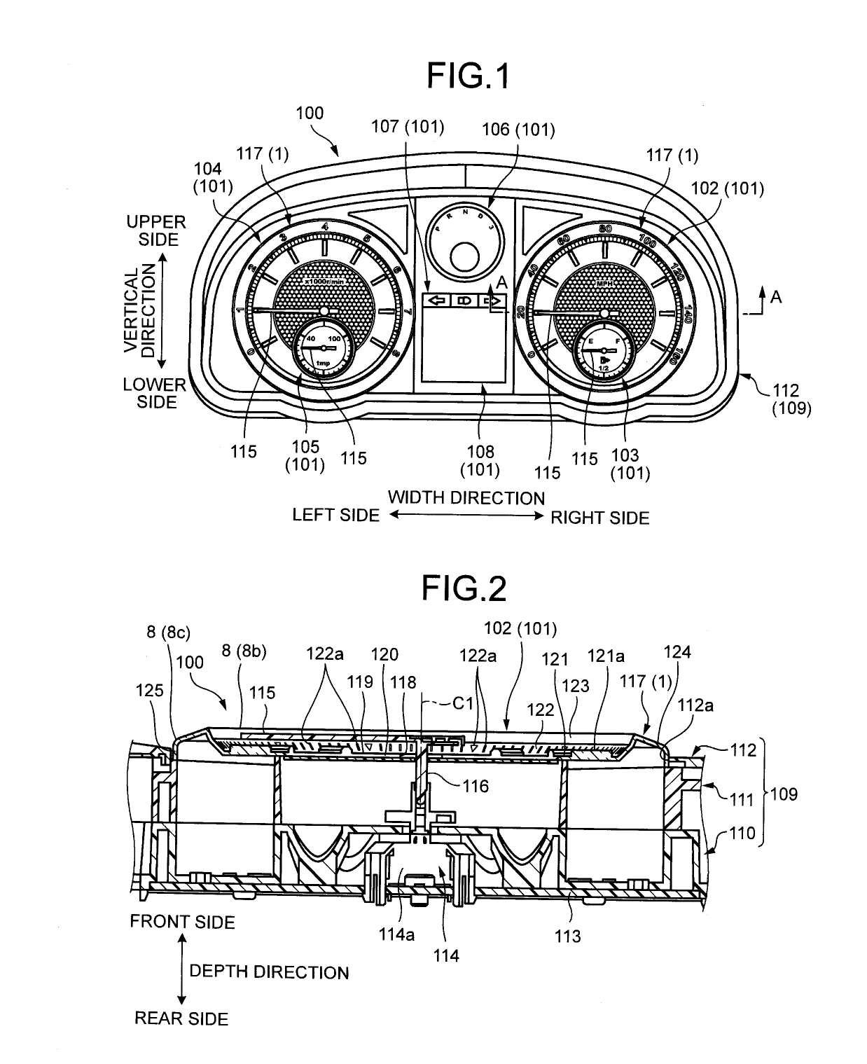

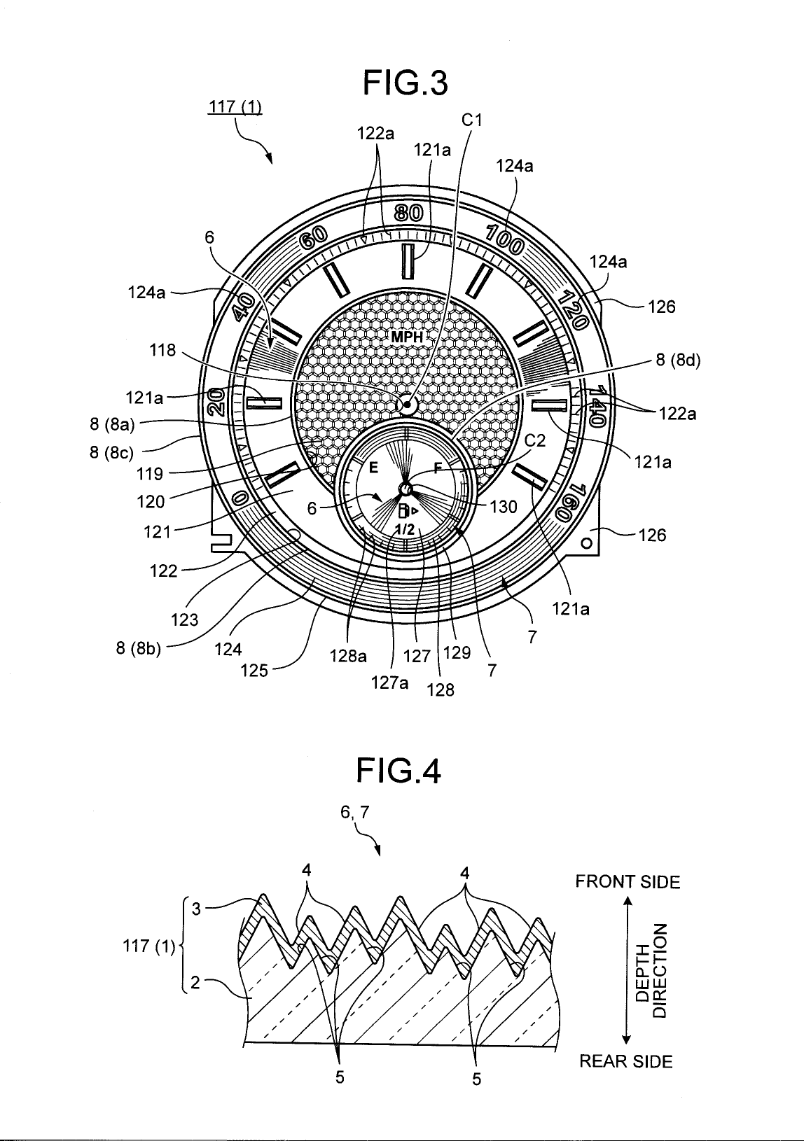

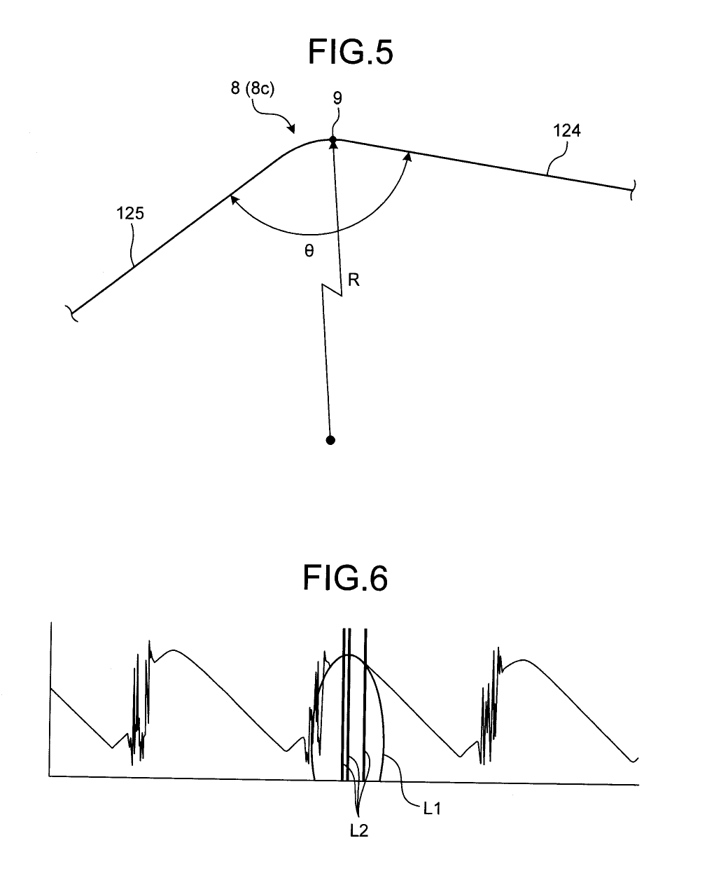

FIG. 1 is a front view illustrating an overall configuration of a vehicle display device according to an embodiment. FIG. 2 is a partial sectional view along A-A in FIG. 1. FIG. 3 is a front view illustrating an overall configuration of a dial plate applied to the vehicle display device according to the embodiment. FIG. 4 is a schematic sectional view illustrating an overall configuration of the dial plate applied to the vehicle display device according to the embodiment. FIG. 5 is a schematic diagram illustrating the curvature radius of the corner that forms the apex of a groove in the dial plate applied to the vehicle display device according to the embodiment. FIG. 6 is a chart illustrating an example of measurement data for the dial plate applied to the vehicle display device according to the embodiment.

As illustrated in FIGS. 1 and 2, decorative parts 1 as metallic decorative parts for a vehicle display device according to the embodiment are applied to a vehicle display device 100 that is mounted on a vehicle. The vehicle display device 100 constitutes what is called an in-vehicle meter. The vehicle display device 100 is mounted, for example, in an instrument panel disposed on a dashboard of the vehicle. The vehicle display device 100 displays various types of information relating to the vehicle, serving for operation of the vehicle. The vehicle display device 100 includes display units 101 and the decorative parts 1. The display units 101 display information relating to the vehicle. The decorative parts 1 are incorporated into different parts of the vehicle display device 100 including the display units 101. The vehicle display device 100 is configured such that the decorative parts 1 each include a metal thin film 3 affixed to a surface of a substrate body 2 formed of resin. The metal thin film 3 is formed into a predetermined shape to thereby give a viewer appropriate metallic texture.

It is noted that the vehicle display device 100 illustrated in FIG. 1 has a width direction that typically corresponds to the width direction of the vehicle to which the vehicle display device 100 is applied. In the following, the left-hand side facing the front surface of the vehicle display device 100 (left side in FIG. 1) may be referred to, in the width direction of the vehicle display device 100, as the left side in the width direction and the right-hand side facing the front surface of the vehicle display device 100 (right side in FIG. 1) may be referred to, in the width direction of the vehicle display device 100, as the right side in the width direction. In addition, the vehicle display device 100 illustrated in FIG. 2 has a depth direction that typically corresponds to the anterior-posterior direction of the vehicle to which the vehicle display device 100 is applied. Additionally, the vehicle display device 100 has a front surface side that faces a driver's seat of the vehicle and that typically corresponds to a side viewed by a driver sitting in the driver's seat. The vehicle display device 100 has a back surface side that is opposite in the depth direction to the front surface side and that is typically a side housed inside the instrument panel.

The display units 101 display various types of information relating to the vehicle. The display units 101 include, exemplarily as the information relating to the vehicle, a speedometer 102, a fuel indicator 103, a tachometer 104, a coolant temperature indicator 105, a shift indicator 106, a turn indicator 107, and a multi-display 108. Specifically, the speedometer 102 indicates a vehicle speed. The fuel indicator 103 indicates a level of fuel still available for use. The tachometer 104 indicates output speed of a traveling drive power source. The coolant temperature indicator 105 indicates the temperature of coolant. The shift indicator 106 indicates a shift position. The turn indicator 107 indicates an operating condition of a turn signal indicator (winker). The multi-display 108 displays other types of auxiliary driving information. The display units 101 are disposed inside a housing 109 that houses different parts of the vehicle display device 100. The display units 101 have display surfaces of various types of information exposed on the front surface side in the depth direction. The housing 109 is formed, for example, of a resin material. The housing 109 includes, for example, a back surface case 110, an intermediate case 111, and a facing 112. The back surface case 110 is disposed on the back surface side in the depth direction. The intermediate case 111 is disposed on the front surface side in the depth direction of the back surface case 110. The facing 112 is disposed on the front surface side in the depth direction of the intermediate case 111. The display units 101 are disposed inside the space defined by the back surface case 110, the intermediate case 111, and the facing 112. In the housing 109, each of the display units 101 has a display surface exposed on the front surface side in the depth direction via an opening 112a (refer to FIG. 2) formed in the facing 112. The display units 101 are configured such that the fuel indicator 103 has a display surface incorporated in a display surface of the speedometer 102 and the coolant temperature indicator 105 has a display surface incorporated in a display surface of the tachometer 104. The display units 101 are configured such that, in the housing 109, the speedometer 102 and the fuel indicator 103 are disposed on the right side in the width direction, the tachometer 104 and the coolant temperature indicator 105 are disposed on the left side in the width direction, and the shift indicator 106, the turn indicator 107, and the multi-display 108 are disposed in the middle therebetween.

As illustrated in FIG. 2, the speedometer 102, for example, includes an internal mechanism 114 that is fixed to a wiring board 113 disposed inside the housing 109. The internal mechanism 114 includes a motor 114a that serves as a drive source for a needle pointer 115. The needle pointer 115 includes a rotational shaft 116 provided in a protruding manner from the motor 114a. The fuel indicator 103, the tachometer 104, and the coolant temperature indicator 105 are configured substantially similarly to the speedometer 102. The facing 112 covers the wring board 113 and the internal mechanism 114, for example. The facing 112 allows each of the display units 101 (the speedometer 102, the fuel indicator 103, the tachometer 104, the coolant temperature indicator 105, the shift indicator 106, the turn indicator 107, the multi-display 108, and the like) to have display surfaces exposed on the front surface side in the depth direction via the opening 112a as described above. It is noted that the vehicle display device 100 has the front surface side in the depth direction of the respective display units 101 protected by a transparent cover fitted to the housing 109.

The decorative parts 1 serve as ornamental members for portions that are, in the vehicle display device 100, exposed on the front surface side in the depth direction and visible from occupants including the driver. The decorative parts 1 are applied to dial plates 117 incorporated in, for example, the respective display units 101, such as the speedometer 102, the fuel indicator 103, the tachometer 104, and the coolant temperature indicator 105. The dial plates 117 constitute display surfaces exposed on the front surface side in the depth direction from the opening 112a of the facing 112 in, for example, the speedometer 102, the fuel indicator 103, the tachometer 104, and the coolant temperature indicator 105. The dial plate 117 includes decoration of a scale pointed by the needle pointer 115 and decoration of various patterns, symbols, character strings, and the like relating to measured values assigned to the corresponding scale.

The following illustrates the dial plates 117 incorporated in the speedometer 102 and in the fuel indicator 103 incorporated in the display surface of the speedometer 102, with reference to, for example, FIGS. 2, 3, and 4. It is noted that the dial plates 117 incorporated in the tachometer 104 and in the coolant temperature indicator 105 incorporated in the display surface of the tachometer 104 are similarly configured.

The dial plate 117 configured as the decorative part 1 has a surface of the front surface side in the depth direction constituting a display surface. The dial plate 117 is generally formed into a substantially circular shape. The dial plate 117 has a shaft hole 118 formed in an area that includes a central axis C1 of the substantially circular shape. The shaft hole 118 receives the rotational shaft 116 of the needle pointer 115 of the speedometer 102 passed therethrough. The shaft hole 118 passes through the dial plate 117 in the depth direction. The shaft hole 118 is formed into a substantially circular shape about the central axis C1. The dial plate 117 includes a center disc section 119, a boundary rising surface 120, a speedometer main scale section 121, a speedometer auxiliary scale section 122, a frame wall 123, a speedometer character display section 124, and a cylindrical end section 125 that are formed concentrically about the central axis C1 in sequence outwardly in a radial direction from the shaft hole 118 side into substantially annular rings. The dial plate 117 functions such that the speedometer main scale section 121, the speedometer auxiliary scale section 122, the speedometer character display section 124, and the like constitute a portion corresponding to the display surface of the speedometer 102.

The center disc section 119 is formed into a substantially annular ring on the outside in the radial direction of the shaft hole 118. The center disc section 119 is formed in a honeycomb mesh. A character string is disposed on the center disc section 119 to denote, for example, a unit of a physical quantity indicated by the speedometer 102, in this case “MPH”, for example. The boundary rising surface 120 is connected with the outside in the radial direction of the center disc section 119 and formed into a substantially annular ring. The boundary rising surface 120 is formed as a substantially cylindrical riser surface that protrudes from the center disc section 119 to the front surface side in the depth direction along the central axis C1. The speedometer main scale section 121 is connected with the outside in the radial direction of an end portion on the front surface side in the depth direction of the boundary rising surface 120 and formed into a substantially annular ring. The speedometer main scale section 121 is associated with the physical quantity indicated by the speedometer 102, specifically, the vehicle speed. The speedometer main scale section 121 includes a plurality of main scales 121a pointed by the needle pointer 115. The main scales 121a are formed in a protruding manner at equally spaced intervals along the circumferential direction of the speedometer main scale section 121. The speedometer auxiliary scale section 122 is connected with the outside in the radial direction of the speedometer main scale section 121 and formed into a substantially annular ring. The speedometer auxiliary scale section 122 is slightly inclined with respect to the speedometer main scale section 121. The speedometer auxiliary scale section 122 is associated with the physical quantity indicated by the speedometer 102, specifically, the vehicle speed. The speedometer auxiliary scale section 122 includes a plurality of auxiliary scales 122a pointed by the needle pointer 115. The auxiliary scales 122a are formed in a protruding manner at equally spaced intervals along the circumferential direction of the speedometer auxiliary scale section 122, at intervals shorter than the intervals at which the main scales 121a are formed. The frame wall 123 is connected with the outside in the radial direction of the speedometer auxiliary scale section 122 and formed into a substantially annular ring. The frame wall 123 is slightly inclined with respect to the speedometer auxiliary scale section 122. More specifically, the frame wall 123 is inclined with respect to the speedometer main scale section 121 more sharply than the speedometer auxiliary scale section 122 is. The speedometer character display section 124 is connected with the outside in the radial direction of the frame wall 123 and formed into a substantially annular ring. The speedometer character display section 124 is inclined reversely with respect to the frame wall 123. The speedometer character display section 124 includes a plurality of character strings 124a representing measured values, specifically, the vehicle speed. The character strings 124a include “20”, “40”, “60” and the like that are formed in a protruding manner at equally spaced intervals along the circumferential direction of the speedometer character display section 124. The cylindrical end section 125 is connected with the outside in the radial direction of the speedometer character display section 124 and formed into a substantially annular ring. The cylindrical end section 125 is formed into a substantially cylindrical riser surface that folds back from the speedometer character display section 124 toward the back surface side in the depth direction along the central axis C1. It is noted that the dial plate 117 includes, for example, a mounting section 126 formed on an outer side in the radial direction of the cylindrical end section 125. The mounting section 126 is used for mounting the corresponding dial plate 117 on, for example, the housing 109.

In addition, a fuel indicator disc section 127, a fuel indicator scale section 128, and a boundary annular section 129 are formed in the dial plate 117 so as to be incorporated into portions of the center disc section 119, the boundary rising surface 120, and the speedometer main scale section 121. The dial plate 117 has a shaft hole 130 formed in an area that includes a reference line C2 that extends in parallel with the central axis C1 and that is set at a position offset (in FIG. 3, the position offset downwardly) from the central axis C1. The shaft hole 130 receives the rotational shaft of the needle pointer 115 of the fuel indicator 103 passed therethrough. The shaft hole 130 passes through the dial plate 117 in the depth direction. The shaft hole 130 is formed into a substantially circular shape about the reference line C2. The dial plate 117 includes the fuel indicator disc section 127, the fuel indicator scale section 128, and the boundary annular section 129 that are formed concentrically about the reference line C2 in sequence outwardly in the radial direction from the shaft hole 130 side into substantially annular rings. The dial plate 117 functions such that the fuel indicator disc section 127, the fuel indicator scale section 128, and the like constitute a portion corresponding to the display surface of the fuel indicator 103.

The fuel indicator disc section 127 is formed into a substantially annular ring on the outside in the radial direction of the shaft hole 130. The fuel indicator disc section 127 includes character strings 127a representing a physical quantity indicated by the fuel indicator 103, specifically, the character strings 127a such as “½”, “E (the first letter of Empty), and “F (the first letter of Full), and various patterns. The fuel indicator scale section 128 is connected with the outside in the radial direction of the fuel indicator disc section 127 and formed into a substantially annular ring. The fuel indicator scale section 128 is associated with the physical quantity indicated by the fuel indicator 103, specifically, the level of fuel still available for use. The fuel indicator scale section 128 includes a plurality of scales 128a indicated by the needle pointer 115. The scales 128a are formed at equally spaced intervals along the circumferential direction of the fuel indicator scale section 128. The boundary annular section 129 is connected with the outside in the radial direction of the fuel indicator scale section 128 and formed into a substantially annular ring. The boundary annular section 129 is disposed between two different areas, one area including the center disc section 119, the boundary rising surface 120, and the speedometer main scale section 121, and the other area including the fuel indicator disc section 127 and the fuel indicator scale section 128. The boundary annular section 129 functions as a boundary between an area that functions as the display surface of the speedometer 102 and an area that functions as the display surface of the fuel indicator 103.

The dial plates 117 configured as the decorative parts 1 in the present embodiment each include the substrate body 2, the metal thin film 3, and a plurality of grooves 4. Specifically, the substrate body 2 is molded from synthetic resin. The metal thin film 3 is formed of metal and deposited on a surface of the substrate body 2. The grooves 4 are formed in a surface of the metal thin film 3 in accordance with the shape of the surface of the substrate body 2. The dial plate 117 has a layered structure including the metal thin film 3 stacked on the surface of the substrate body 2. The surface of the metal thin film 3 constitutes the display surface of the dial plate 117. The grooves 4 formed in the display surface give a predetermined area a patterned decoration.

It should here be noted that the surface of each of the substrate body 2 and the metal thin film 3 is on the front surface side in the depth direction, specifically, the surface opposed to the driver's seat of the vehicle. Typically, the surface of the metal thin film 3 is visually recognized by, for example, the driver sitting in the driver's seat.

Integral molding of synthetic resin using a mold integrally molds the following elements described above of the substrate body 2: specifically, the center disc section 119, the boundary rising surface 120, the speedometer main scale section 121, the speedometer auxiliary scale section 122, the frame wall 123, the speedometer character display section 124, the cylindrical end section 125, the mounting section 126, the fuel indicator disc section 127, the fuel indicator scale section 128, the boundary annular section 129, the main scales 121a, the auxiliary scales 122a, the character strings 124a, the character strings 127a, and the scales 128a. The metal thin film 3 is deposited on the surface of the substrate body 2. The grooves 4 are formed in the surface of the metal thin film 3 in accordance with the shape of the surface of the substrate body 2. In other words, the substrate body 2 has grooves 5 formed in the surface covered by the metal thin film 3 in accordance with the shape of the grooves 4 formed in the surface on which the metal thin film 3 is deposited. During integral molding of the substrate body 2 from the synthetic resin using the mold, grooves formed in a molded surface of the mold are transferred onto the surface of the substrate body 2 to form the grooves 5.

The grooves 4 in the present embodiment form various mark patterns on the surface of the dial plate 117. Exemplarily, the dial plates 117 in the present embodiment are marked with what is called a radial mark pattern 6 and what is called a spin mark pattern 7. The radial mark pattern 6 is applied by the grooves 4 to the surfaces of the speedometer main scale section 121 and the fuel indicator disc section 127. The spin mark pattern 7 is applied by the grooves 4 to the surfaces of the speedometer character display section 124 and the fuel indicator scale section 128. The radial mark pattern 6 is formed by the fine grooves 4 extending radially from a preset reference point (e.g., a point on the central axis C1 or the reference line C2) or a point nearby the preset reference point outwardly. The radial mark pattern 6 may at times be referred to as a rising-sun pattern. The spin mark pattern 7 is formed by the fine grooves 4 extending in a concentric annular ring shape or a spiral ring shape about a preset reference point (e.g., a point on the central axis C1 or the reference line C2).

The dial plate 117 of the present embodiment further includes a ridge 8 formed in a predetermined shape to ensure more appropriate metallic texture. The ridge 8 is formed with different surfaces intersecting at the surface of the metal thin film 3 in conformity with the shape of the surface of the substrate body 2 and typically functions as a boundary between different regions. The ridge 8 forms a joint corner (external corner) of surfaces with different angles. The ridge 8 may be a boundary between regions of different patterns or may be a boundary between regions of similar patterns or no patterns. The dial plate 117 includes a plurality of ridges 8. Here, the ridges 8 include a ridge 8a formed with the boundary rising surface 120 and the speedometer main scale section 121 intersecting each other, a ridge 8b formed with the frame wall 123 and the speedometer character display section 124 intersecting each other, a ridge 8c formed with the speedometer character display section 124 and the cylindrical end section 125 intersecting each other, and a ridge 8d formed with the fuel indicator scale section 128 and the boundary annular section 129 intersecting each other. The ridge 8a is a boundary line between the boundary rising surface 120 having a mirror surface and the speedometer main scale section 121 having a surface furnished with the radial mark pattern 6. The ridge 8b is a boundary line between the frame wall 123 having a mirror surface and the speedometer character display section 124 having a surface furnished with the spin mark pattern 7. The ridge 8c is a boundary line between the speedometer character display section 124 having a surface furnished with the spin mark pattern 7 and the cylindrical end section 125 having a mirror surface. The ridge 8d is a boundary line between the fuel indicator scale section 128 having a surface furnished with the spin mark pattern 7 and the boundary annular section 129 having a mirror surface. In the following description, the ridge 8a, the ridge 8b, the ridge 8c, and the ridge 8d will be simply referred to as ridge 8 unless they need to be distinguished from each other.

The ridge 8 in the present embodiment is formed such that the curvature radius R of the corner 9 that forms the apex of the ridge is greater than 0 and equal to or smaller than 28.0 μm. More specifically, a plurality of ridges 8 are each formed so as to satisfy the conditional expression presented as expression (1) below where “R” is the curvature radius of the corner 9 that forms the apex.

0<R≦28.0 μm (1)

More preferably, the ridges 8 are each formed such that the curvature radius R of the corner 9 that forms the apex of the ridge is greater than 0 and equal to or smaller than 10.0 μm. That is, more preferably, the ridges 8 are each formed so as to satisfy the conditional expression represented as expression (2) below.

0<R≦10.0 μm (2)

The lower limit of the curvature radius R of the corner 9 that forms the apex of the ridge 8 is typically in a range possible in production.

Here, the curvature radius R of the corner 9 that forms the apex of the ridge 8 corresponds to the radius of an arc in contact with the corner 9 as illustrated in FIG. 5. In the dial plate 117 formed as the decorative part 1, all of the ridges 8 are shaped such that the curvature radius R of the corner 9 that forms the apex as measured according to a predetermined measurement condition satisfies any of the conditional expressions represented as expressions (1) and (2) above. The example illustrated in FIG. 5 represents the ridge 8c that is the boundary line between the speedometer character display section 124 having a surface furnished with the spin mark pattern 7 and the cylindrical end section 125 having a mirror surface. The angle θ formed by different surfaces that form the ridge 8c, here, the surface of the speedometer character display section 124 and the surface of the cylindrical end section 125, is greater than 90°, that is, the corner 9 of the ridge 8c has an obtuse angle. In other words, the different surfaces that form the ridge 8c intersect each other at an angle greater than 90°.

An example of the predetermined measurement condition for measuring the curvature radius R of the corner 9 that forms the apex of the ridge 8 is as follows. That is, a “3D laser measuring microscope LEXT OLS4000 manufactured by OLYMPUS CORPORATION” is used as a measuring instrument, for measuring the curvature radius R, in the steps below.
Step 1 An image of the surface of the dial plate 117 formed as the decorative part 1 is captured in the “imaging” mode with a “3D laser measuring microscope LEXT OLS4000 manufactured by OLYMPUS CORPORATION”.
Step 2 After capturing the image, in the operation screen of the “3D laser measuring microscope LEXT OLS4000 manufactured by OLYMPUS CORPORATION” (which hereinafter may be simply referred to as “operation screen”), the “measurement” tab is selected to switch the mode to “measurement”, and the “profile measurement” is selected. As a result, the profile data (outline data) of the surface of the dial plate 117 as illustrated in FIG. 6 appears on the operation screen.
Step 3 Next, in the “specify measurement items” in the operation screen, “curvature” is selected. With this operation, a circle L1 and straight lines L2 appear in the profile data of the surface of the dial plate 117 displayed at Step 2. Moving the straight lines L2 to the right and the left on the profile data changes the size of the circle L1.
Step 4 The straight lines L2 displayed on the profile data of the surface of the dial plate 117 are moved to match the circle L1 with the curve of the corner 9 that forms the apex of the ridge 8. The radius of the circle L1 matched with the curved surface of the corner 9 in this way is the measured value of the curvature radius R of the corner 9 that forms the apex of the ridge 8.

In the dial plate 117 formed as the decorative part 1, the corner 9 that forms the apex of the ridge 8 is formed in a shape that satisfies any of the conditional expressions represented as expressions (1) and (2) above, whereby sharpness close to a groove formed by cutting work on actual metal can be reproduced in the ridge 8 where different surfaces intersect each other.

In order for the dial plate 117 configured as the decorative part 1 to achieve the shape that satisfies any one of the conditional expressions of expressions (1) and (2) given above, preferably, synthetic resin that exhibits high fluidity and favorable transfer performance (or, ability to follow the profile of the molding surface), specifically, a cycloolefin polymer (COP) resin, is used as the synthetic resin that forms the substrate body 2 and titanium is used as the metal that forms the metal thin film 3. Additionally, preferably, the metal thin film 3 that contains titanium is deposited through what is called sputtering on the surface of the substrate body 2 that has been molded using a mold into a predetermined shape from synthetic resin that contains the cycloolefin polymer resin.

More specifically, the substrate body 2 is molded through integral molding from the synthetic resin that contains the cycloolefin polymer resin. In this case, the mold for molding the substrate body 2 has a molding surface on which formed are not only portions where the different parts of the dial plates 117 described above (including the center disc section 119, the boundary rising surface 120, the speedometer main scale section 121, the speedometer auxiliary scale section 122, the frame wall 123, the speedometer character display section 124, the cylindrical end section 125, the mounting section 126, the fuel indicator disc section 127, the fuel indicator scale section 128, the boundary annular section 129, the main scales 121a, the auxiliary scales 122a, the character strings 124a, the character strings 127a, the scales 128a and the like, and the ridges 8) are formed, but also the grooves formed in accordance with the shape of the grooves 4 that constitute the radial mark pattern 6 and the spin mark pattern 7 described above. Basic shapes corresponding to the different parts of the dial plates 117 are formed in the mold using various types of machine tools, e.g., a numerical control (NC) milling machine, on the basis of machining information including shape information of the molding surface of the mold. In this case, for the formation of the fine grooves in the molding surface of the mold in accordance with the grooves 5, the fine grooves in accordance with the grooves 5 are cut in the molding surface of the mold using various types of cutting tools, e.g., an end mill and a diamond cutting tool, instead of by etching, buffing, or grinding. The grooves formed in the molding surface of the mold are transferred onto the surface of the substrate body 2, so that the grooves 5 in accordance with the shape of the grooves 4 that constitute the radial mark pattern 6 and the spin mark pattern 7 are formed in the substrate body 2.

The metal thin film 3 is deposited on the surfaces of the substrate body 2 to provide an outer covering through the film deposition of titanium by sputtering performed on the surfaces of the substrate body 2 on which the different parts of the dial plates 117 and the ridges 8 and in which the grooves 5 in accordance with the shape of the grooves 4 that constitute the radial mark pattern 6 and the spin mark pattern 7 are formed. The sputtering, as used herein, refers to a process in which a DC high voltage is applied to an inert gas, such as argon, packed in a vacuum chamber to thereby ionize the inert gas; the ionized inert as is made to collide with a metal ingot, specifically in this case, a titanium ingot; titanium molecules/atoms as metal particles repelled from the ingot are deposited onto the surface of the substrate body 2 as a target; a titanium metal thin film 3 is thereby deposited on the surface of the target substrate body 2. The sputtering achieves relatively greater adhesion of the metal thin film 3 to the substrate body 2.

As described above, the substrate body 2 is molded using the cycloolefin polymer resin, which is synthetic resin that exhibits high fluidity and favorable transfer performance. The molding of the substrate body 2 enables any desired shape required by, for example, the different parts of the dial plates 117 and the ridges 8 and the grooves 5 in accordance with the shape of the grooves 4 that constitute the radial mark pattern 6 and the spin mark pattern 7 that are formed in the molding surface of the mold to be faithfully transferred from the molding surface to the surface of the substrate body 2.

The metal thin film 3 is formed such that a film of titanium, which exhibits favorable adhesion to the substrate body 2 molded from the cycloolefin polymer resin and permits sputtering, is deposited on the surface of the substrate body 2 by sputtering. Thus, the metal thin film 3 can achieve sufficient adhesion to the substrate body 2 without the need to have, for example, an undercoat on the surface of the substrate body 2, thus reducing a chance of the metal thin film 3 separating from the substrate body 2. Formed to contain titanium, which is materially stable, the metal thin film 3 does riot require, for example, a top coat on the surface thereof, either. As a result, the metal thin film 3 can be formed to be relatively thin (e.g., about 0.2 μm), so that the grooves 4 that constitute the radial mark pattern 6 and the spin mark pattern 7 can be formed without the need to fill the grooves 5 formed in the surface of the substrate body 2.

The decorative part 1 (dial 117) described above includes the substrate body 2 molded with synthetic resin, the metal thin film 3 formed of metal and deposited on the surface of the substrate body 2, and the ridge 8 formed with different surfaces intersecting at the surface of the metal thin film 3 in conformity with the shape of the surface of the substrate body 2. The ridge 8 is formed such that the curvature radius R of the corner 9 that forms the apex of the ridge is greater than 0 and equal to or smaller than 28.0 μm. More preferably, the ridge 8 is formed such that the curvature radius R of the corner 9 that forms the apex of the ridge is greater than 0 and equal to or smaller than 10.0 μm. The vehicle display device 100 described above includes the display unit 101 displaying information related to the vehicle and the aforementioned decorative part 1 (dial 117).

In the decorative part 1 (dial 117) and the vehicle display device 100, the ridge 8 formed with different surfaces intersecting at the surface of the metal thin film 3 in conformity with the shape of the surface of the substrate body 2 formed by resin molding is shaped such that the curvature radius R of the corner 9 that forms the apex of the ridge 8 satisfies any of the conditional expressions represented as expressions (1) and (2) above, whereby sharpness close to a groove formed by cutting work on actual metal can be reproduced in the ridge 8. In the decorative part 1 and the vehicle display device 100, with the configuration having the metal thin film 3 formed on the surface of the substrate body 2 that is a resin molded product, variation in quality can be reduced, while texture close to actual metal can be reproduced in spite of the resin molded product as described above. For example, the decorative part 1 and the vehicle display device 100 can be manufactured with lower costs than when the decorative part 1 is individually produced by machining, and has a smaller weight than when the decorative part 1 is entirely produced from metal, which contributes weight reduction of the vehicle tower costs and light weight of the decorative part 1 and the vehicle display device 100 thus can be achieved. Thus, the decorative part 1 and the vehicle display device 100 configured to have the metal thin film 3 on the resin substrate body 2 can appropriately provide metallic texture for viewers.

In the decorative part 1 (dial 117) described above, the angle θ formed by different surfaces that form the ridge 8c is greater than 90° (refer to FIG. 5). In this case, in the decorative part 1 ((dial 117) and the vehicle display device 100, the ridge 8c shaped such that the curvature radius R of the corner 9 satisfies any of the conditional expressions represented as expressions (1) and (2) is applied to the section where different surfaces intersect at an obtuse angle, whereby the ridge 8c, where sharpness is less distinguishable because of its obtuse angle, looks sharp more noticeably. Thus, the decorative part 1 and the vehicle display device 100 having the metal thin film 3 on the surface of the resin substrate body 2 can more appropriately provide metallic texture for viewers.

Additionally, in the decorative parts 1 (dial plates 117) described above, the substrate body 2 is molded to contain cycloolefin polymer resin and the metal thin film 3 is formed to contain titanium. Consequently, the decorative parts 1 and the vehicle display device 100 enables a combination of the substrate body 2 and the metal thin film 3 to achieve, for example, favorable transfer performance in the substrate body 2 constituting the decorative parts 1, the ability to follow the profile through machinability and thinning of the metal than film 3 constituting the decorative parts 1, and favorable adhesion between the substrate body 2 and the metal thin film 3. Molded to contain the cycloolefin polymer resin, the substrate body 2 enables any desired shape required by, for example, the different parts of the dial plates 117 and the ridges 8 and the grooves 5 in accordance with the shape of the grooves 4 that constitute the radial mark pattern 6 and the spin mark pattern 7 that are formed in the molding surface of the mold, to be faithfully transferred from the molding surface to the surface of the substrate body 2. Formed using titanium, permits thin film deposition by sputtering, the metal thin film 3 allows film thickness to be made relatively thin, and enables the grooves 4 that constitute the radial mark pattern 6 and the spin mark pattern 7 to be formed without the need to fill the grooves 5 formed in the surface of the substrate body 2. Moreover, sufficient adhesion can be achieved between the substrate body 2 and the metal thin film 3, so that the metal thin film 3 can be prevented from being separated from the substrate body 2. Also in the foregoing respect, the decorative parts 1 and the vehicle display device 100 can appropriately gain metallic texture to he given to the viewer in the configuration of the metal thin film 3 formed on the surface of the substrate body 2 formed of resin.

It is understood that the metallic decorative part for a vehicle display device and the vehicle display device according to the embodiment described above are for illustrative purpose only and are not limiting and that various changes may be made without departing from the scope of the present invention.

It has been described above that the decorative parts 1 are applied to the dial plates 117 that are incorporated in, for example, the speedometer 102, the fuel indicator 103, the tachometer 104, and the coolant temperature indicator 105, but are not limiting. The decorative parts 1 may be applied, in the vehicle display device 100, to other ornamental members for portions that are exposed on the front surface side in the depth direction and visible from the occupants including the driver. The decorative parts 1 may be applied to the facing 112 and annular ornamental members (ring members) disposed around, for example, the speedometer 102, the fuel indicator 103, the tachometer 104, and the coolant temperature indicator 105.

It has been described above that the dial plates 117 have the radial mark pattern 6 applied to the surface of the speedometer main scale section 121 and the fuel indicator disc section 127, and the spin mark pattern 7 applied to the surface of the speedometer character display section 124 and the fuel indicator scale section 128. The foregoing is, however, illustrative only and not limiting. For example, the dial plates 117 may be provided with any pattern other than the radial mark pattern 6 and the spin mark pattern 7, by the grooves 4. For example, the dial plates 117 may be provided with a hairline mark pattern having vertical stripes formed by the grooves 4, a hairline mark pattern having lateral stripes formed by the grooves 4, or a mark pattern having vertical stripes crossing lateral stripes.

It has been described above that the cycloolefin polymer resin is used as the synthetic resin that forms the substrate body 2, titanium is used as the metal that forms the metal thin film 3, and the sputtering is employed to deposit the metal thin film 3 on the surface of the substrate body 2. The foregoing is, however, illustrative only and not limiting. The substrate body 2 may be molded to contain, for example, an acrylic resin or a polycarbonate (PC) resin. The metal thin film 3 may be formed to contain, for example, aluminum, stainless steel, gold, silver, platinum, copper, zinc, nickel, chrome, tin, or molybdenum. Vapor deposition, for example, may be employed as the film deposition process to deposit the metal thin film 3 on the surface of the substrate body 2.

In the foregoing description, a “3D laser measuring microscope LENT OLS4000 manufactured by OLYMPUS CORPORATION” is used as a measuring instrument for measuring the curvature radius R of the corner 9 that forms the apex of the ridge 8. However, the measuring instrument is not limited thereto and any other measuring instruments may be used. In this case, a predetermined measurement condition for measuring the curvature radius R of the corner 9 that forms the apex of the ridge 8 is set equivalent to the one described above.

### EXAMPLES

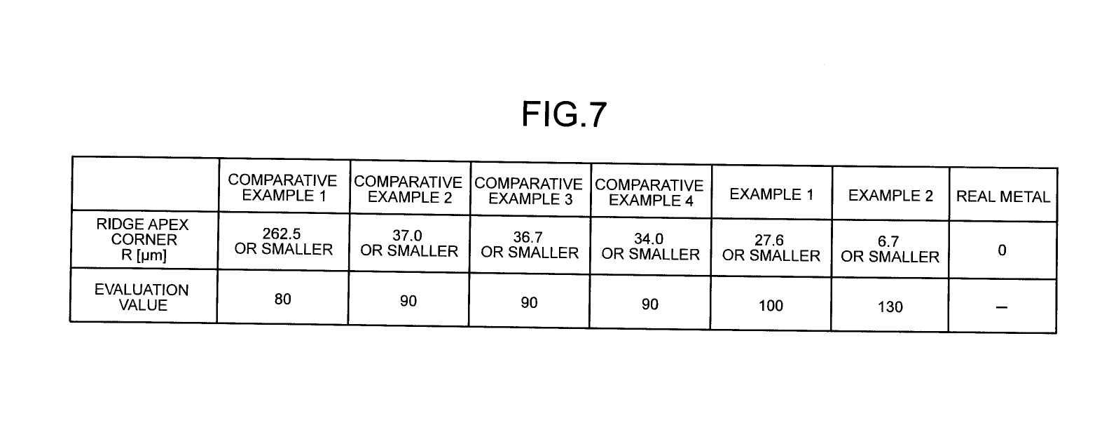

FIG. 7 is a diagram illustrating the results of a sensory evaluation test for the dial plate according to examples. Referring to FIG. 7, a sensory evaluation test for the dial plate 117 formed as the decorative part 1 will be described below.

In this sensory evaluation test, the dial plate 117 formed as the decorative part 1 according to the foregoing embodiment was actually produced, in which the curvature radius R of the corner 9 that forms the apex of the ridge 8 satisfies any of the conditional expressions represented as expressions (1) and (2) above. In “Example 1”, ridges 8 were formed such that the curvature radius R of the corner 9 that forms the apex was equal to or smaller than 27.6 μm in all of the ridges 8, and expression (1) is satisfied. In “Example 2”, ridges 8 were formed such that the curvature radius R of the corner 9 that forms the apex was equal to or smaller than 6.7 μm in all of the ridges 8, and expressions (1) and (2) are satisfied. By comparison, in “Comparative Example 1”, “Comparative Example 2”, “Comparative Example 3”, and “Comparative Example 4” actually produced, the curvature radius R of the corner 9 that forms the apex of the ridge 8 does not satisfy any of the conditional expressions represented as expressions (1) and (2) above. In “Comparative Example 1”, ridges 8 were formed such that the curvature radius R of the corner 9 that forms the apex was equal to or smaller than 262.5 μm in all of the ridges 8, and the curvature radius R at least greater than 28.0 μm was included. In “Comparative Example 2”, ridges 3 were formed such that the curvature radius R of the corner 9 that forms the apex was equal to or smaller than 37.0 μm in all of the ridges 8, and the curvature radius R at least greater than 28.0 μm was included. In “Comparative Example 3”, ridges 8 were formed such that the curvature radius R of the corner 9 that forms the apex was equal to or smaller than 36.7 μm in all of the ridges 8, and the curvature radius R at least greater than 28.0 μm was included. In “Comparative Example 4”, ridges 8 were formed such that the curvature radius R of the corner 9 that forms the apex was equal to or smaller than 34.0 μm in all of the ridges 8, and the curvature radius R at least greater than 28.0 μm was included. In “Example 1”, “Example 2”, “Comparative Example 1”, “Comparative Example 2”, “Comparative Example 3”, and “Comparative Example 4”, cyclo-olefin polymer resin was used as the synthetic resin to form the substrate body 2, titanium was used as the metal to form the metal thin film 3, and the metal thin film 3 was deposited on the surface of the substrate body 2 by sputtering, in the same manner as in the foregoing embodiment. The curvature radius R of each corner 9 in “Example 1”, “Example 2”, “Comparative Example 1”, “Comparative Example 2”, “Comparative Example 3”, and “Comparative Example 4” was the measured value obtained by measurement through Step 1 to Step 4 above using a “3D laser measuring microscope LEXT OLS4000 manufactured by OLYMPUS CORPORATION”. A ridge 8 was actually formed by cutting work on a dial plate having a similar structure produced from real metal, and the corner 9 that forms the apex of the ridge 8 was measured in the same way. In this case, the curvature radius R is “0”.

The sensory evaluation test was conducted for the “first example”, the “second example”, the “first comparative example”, the “second comparative example”, the “third comparative example”, and the “fourth comparative example” as evaluation objects using the following procedure. Specifically, evaluators made a sensory evaluation of metallic texture of each of the evaluation objects on the basis of their experience, when the evaluation objects and the present metal were placed in: (A-1) a room having no extraneous light and at predetermined positions within a prototype of the vehicle display device 100 illustrated in FIG. 1 in juxtaposition with each other; (A-2) a room having extraneous light and at predetermined positions within the prototype of the vehicle display device 100 illustrated in FIG. 1 in juxtaposition with each other; (B-1) a room having no extraneous light, and at predetermined positions within a box having an acrylic top plate (something like an exhibition case) in juxtaposition with each other and with all areas surrounding all but the evaluation objects covered in a black cloth; and (B-2) a room having extraneous light, and at predetermined positions within a box having an acrylic top plate in juxtaposition with each other and with all areas surrounding all but the evaluation objects covered in a black cloth. The evaluators finally made an overall evaluation for a combination of all of (A-1), (A-2), (B-1), and (B-2). The evaluation value was rated as “100” when sufficient metallic texture was sensed with no deliberate intention evident to achieve the sufficient metallic texture as compared with the present metal, and rated as “less than 100” when sufficient metallic texture was not sensed with some deliberate intention evident, to achieve the sufficient metallic texture as compared with the present metal. Greater evaluation values above “100” signify an increasing sense of metallic texture, and smaller evaluation values below “100” signify a decreasing sense of metallic texture. Designers of the vehicle display devices (meters) formed a group of five evaluators and the evaluation value was an average value of the evaluation values rated by the five evaluators. The sensory evaluation test was conducted for each of the evaluation objects.

According to the sensory evaluation test, as is clear from FIG. 7, the evaluation value of “Comparative Example 1” is “80”, the evaluation value of “Comparative Example 2” is “90”, the evaluation value of “Comparative Example 3” is “90”, and the evaluation value of “Comparative Example 4” is “90”. These results indicate that the comparative examples look artificial when compared with metal and do not provide satisfactory metallic texture. By contrast, the evaluation value of “Example 1” is “100”, and the evaluation value of “Example 2” is “130”. These results clearly indicate that the examples do not look artificial when compared with real metal and provide satisfactory metallic texture. In “Example 1” and “Example 2”, the metallic texture obviously increases as the curvature radius R of the corner 9 that forms the apex of the ridge 8 relatively decreases, and metallic texture is obviously better in “Example 2”. As described above, it is clear that “Example 1” and “Example 2” having the metal thin film formed on the surface of the resin substrate body 2 appropriately provide metallic texture for viewers and has metallic appearance.

In the metallic decorative part for a vehicle display device and the vehicle display device according to the embodiements, the ridge formed with different surfaces intersecting at the surface of the metal thin film in conformity with the shape of the surface of the substrate body formed by resin molding is formed such that the curvature radius of the corner that forms the apex of the ridge is greater than 0 and equal to or smaller than 28.0 μm, whereby sharpness close to a ridge formed by cutting work on actual metal can be reproduced in the ridge. In the metallic decorative part for a vehicle display device and the vehicle display device, with the configuration having the metal thin film formed on the surface of the substrate body that is a resin molded product, variation in quality can be reduced, while texture close to actual metal can be reproduced in spite of the resin molded product as described above. Thus, the metallic decorative part for a vehicle display device and the vehicle display device having the metal thin film on the surface of the resin substrate body can appropriately provide metallic texture for viewers.

Although the invention has been described with respect to specific embodiments for a complete and clear disclosure, the appended claims are not to be thus limited but are to he construed as embodying all modifications and alternative constructions that may occur to one skilled in the art that fairly fall within the basic teaching herein set forth.

What is claimed is:

1. A metallic decorative part for a vehicle display device, the metallic decorative part comprising:
a substrate body molded with synthetic resin;
a metal this film that is formed of metal and deposited on a surface of the substrate body; and
a ridge that is formed with different surfaces intersecting at a surface of the metal thin film in conformity with a shape of the surface of the substrate body, wherein
the ridge is formed such that a curvature radius of a corner that forms an apex of the ridge is greater than 0 and equal to or smaller than 28.0 μm.

2. The metallic decorative part for a vehicle display device according to claim 1, wherein
the ridge is formed such that the curvature radius of the corner that forms the apex of the ridge is greater than 0 and equal to or smaller than 10.0 μm.

3. The metallic decorative part for a vehicle display device according to claim 1, wherein
an angle formed by the different surfaces that form the ridge is greater than 90°.

4. A vehicle display device comprising:
a display unit that displays information relating to vehicle; and
a metallic decorative part for a vehicle display device that includes a substrate body molded with synthetic resin, a metal thin film that is formed of metal and deposited on a surface of the substrate body, and a ridge that is formed with different surfaces intersecting at a surface of the metal thin film in conformity with a shape of the surface of the substrate body, wherein
the ridge is formed such that a curvature radius of a corner that forms an apex of the ridge is greater than 0 and equal to or smaller than 28.0 μm.

5. The metallic decorative part for a vehicle display device according to claim 2, wherein
an angle formed by the different surfaces that form the ridge is greater than 90°.
